(19) United States
(12) Patent Application Publication
(10) Pub. No.: US 2026/0331329 A1
(43) Pub. Date: Oct. 22, 2026

(54) CONDUCTIVE FILM

(71) Applicant: Panasonic Intellectual Property Management Co.,Ltd., Kadoma-shi, Osaka (JP)

(72) Inventors: Keishiro Murata, KYOTO FU (JP); Yutaka Kinugasa, OSAKA FU (JP); Yuji Nonami, SHIGA KEN (JP)

(73) Assignee: Panasonic Intellectual Property Management Co., Ltd., Kadoma-shi, Osaka (JP)

(21) Appl. No.: 19/109,696

(22) PCT Filed: Jul. 10, 2023
(86) PCT No.: PCT/JP2023/025420

§ 371 Date: Mar. 7, 2025

(30) Foreign Application Priority Data
Sep. 22, 2022 (JP) 2022-151358

(51) Int. Cl. H01B 5/14

(52) U.S. Cl. CPC H01B 5/14

(57) ABSTRACT

A first conductive line has a first recess. A second conductive line has a second recess. The groove width dimension of a second groove is greater than the groove width dimension of a first groove. The recess width dimension of the second recess is greater than the recess width dimension of the first recess. The recess depth dimension of the second recess is greater than the recess depth dimension of the first recess.

### TECHNICAL FIELD

The present disclosure relates to a conductive film.

### BACKGROUND ART

Conventionally, for example, a conductive film described in Patent Document 1 has been known as a conductive film applicable to a touch sensor.

Patent Document 1 discloses a touch sensor provided with a display region and a non-display region. The touch sensor includes a translucent cover member (polarizer), a conductive film (touch panel) stacked on the back surface side of the cover member, and a touch panel flexible substrate connected to the conductive film in the non-display region.

The conductive film (touch panel) includes a substrate, a plurality of electrodes (touch electrodes) provided on the front surface of the substrate and disposed in the display region, and a plurality of routing wires (peripheral lines) disposed in the non-display region.

Each electrode includes a plurality of conductive lines disposed in a mesh pattern on the front surface side of the substrate. Each routing wire includes a conductive line formed of a single line disposed on the front surface side of the substrate. Each conductive line is formed of a conductive layer in which a metal material having conductivity is embedded in a bottomed groove (conductive layer forming groove, line forming groove) formed on the front surface of the substrate. The outer surface of the conductive layer is disposed so as to face the cover member (polarizer). The outer surface of the conductive layer is configured to be a flat surface flush with the front surface of the substrate.

The touch panel flexible substrate is connected to an end portion of the conductive film on one long side thereof. The conductive line forming the routing wire is electrically connected to a terminal of the touch panel flexible substrate via an anisotropic conductive resin material (anisotropic conductive film) in a touch panel flexible substrate mounting region.

### CITATION LIST

### Patent Documents

Patent Document 1: Japanese Unexamined Patent Publication No. 2019-121311

### SUMMARY OF THE INVENTION

### Technical Problems

As described above, in the conductive film of Patent Document 1, external light having entered the touch sensor from the outside of the touch sensor (i.e., from the front surface side of the cover member) is reflected (i.e., specularly reflected) toward the cover member over the outer surface of the conductive layer because the outer surface of the conductive layer is the flat surface. Accordingly, the plurality of conductive lines forming each electrode becomes conspicuous when a user views the touch sensor. That is, the plurality of electrodes located in the display region becomes conspicuous. As a result, the visibility of the display region is lowered.

Since the outer surface of the conductive layer is the flat surface, for example, in the course of manufacturing the touch sensor, in a case where a film (hereinafter referred to as a “process protective film”) for protecting the outer surface of the conductive layer is repeatedly attached to the conductive film or the process protective film is repeatedly detached from the conductive film, part of an outer surface side portion of the conductive layer is easily detached from the groove. As a result, the conductive layer may easily corrode, or the conductive layer may be damaged due to ESD breakdown. That is, in the conductive film of Patent Document 1, the state of the conductive line is not properly maintained, and therefore, the conduction reliability of the conductive line may be impaired.

Further, since the outer surface of the conductive layer is the flat surface, it is assumed that conductive particles contained in the anisotropic conductive resin material are in point contact with the outer surface of the conductive layer in the touch panel flexible substrate mounting region located in the non-display region. That is, the area of contact between the conductive particles and the conductive layer is relatively small. For this reason, an electrical connection state between the conductive particles and the conductive line forming the routing wire is likely to be unstable. As a result, there is a possibility that the conduction reliability of the conductive line located in the non-display region cannot be sufficiently obtained.

The present disclosure has been made in view of the above-described points, and it is an object of the present disclosure to improve the visibility of a conductive film and ensure the conduction reliability of a conductive line the conductive film.

### Solution to the Problem

In order to achieve the above-described object, an embodiment of the present disclosure is a conductive film provided with a first region and a second region, and the conductive film includes a substrate, at least one first conductive line provided on the substrate, and at least one second conductive line provided on the substrate. The substrate has at least one first groove located in the first region, extending linearly, and having a bottomed shape, and at least one second groove located in the second region, extending linearly, and having a bottomed shape. The first conductive line and the second conductive line includes a conductive layer made of a conductive material and embedded in each of the first groove and the second groove. The first conductive line has at least one first recess recessed from the opening side of the first groove in the thickness direction of the substrate in a cross section.

The second conductive line has at least one second recess recessed from the opening side of the second groove in the thickness direction of the substrate in a cross section. The first groove and the second groove are configured such that the groove width dimension of the second groove is greater than the groove width dimension of the first groove. The first recess and the second recess are configured such that the recess width dimension of the second recess is greater than the recess width dimension of the first recess and the recess depth dimension of the second recess is greater than the recess depth dimension of the first recess.

### Advantages of the Invention

According to the present disclosure, it is possible to improve the visibility of the conductive film and ensure the conduction reliability of the conductive line the conductive film.

### BRIEF DESCRIPTION OF THE DRAWINGS

FIG. 1 is an overall perspective view of a touch sensor.

FIG. 2 is a plan view schematically showing a connection state between a conductive film and a flexible wiring board according to an embodiment of the present disclosure.

FIG. 3 is a perspective view schematically showing respective configurations of a substrate, a transmission electrode, a reception electrode, a routing wire, and a connection pad as viewed from the front surface side of the conductive film.

FIG. 4 is a plan view schematically showing respective configurations of the substrate, the transmission electrode, the routing wire, and the connection pad as viewed from the back surface side of the conductive film.

FIG. 5 is a bottom view schematically showing respective configurations of the substrate, the reception electrode, the routing wire, and the connection pad as viewed from the front surface side of the substrate.

FIG. 6 is a cross-sectional view taken along line VI-VI of FIG. 1.

FIG. 7 is a cross-sectional view taken along line VII-VII of FIG. 1.

FIG. 8 is a partially enlarged plan view showing, in closeup, part of the reception electrode.

FIG. 9 is a cross-sectional view taken along line IX-IX of FIG. 8.

FIG. 10 is a partially enlarged plan view showing, in closeup, part of a second conductive line forming the routing wire.

FIG. 11 is a partially enlarged plan view showing, in closeup, part of the second conductive line forming the connection pad.

FIG. 12 is a cross-sectional view taken along line XII-XII of FIG. 10.

FIG. 13 is a cross-sectional view schematically showing a state in which a conductive particle is fitted in a second recess.

FIG. 14 is a partially enlarged plan view showing, in closeup, part of a second conductive line forming a routing wire in a first variation of the embodiment of the present disclosure.

FIG. 15 is a view corresponding to FIG. 12, which schematically shows the cross-sectional structure of a second conductive line in a second variation of the embodiment of the present disclosure.

### DESCRIPTION OF EMBODIMENTS

Embodiments of the present disclosure will be described in detail below with reference to the drawings. The following description of the embodiments is merely exemplary in nature and is not intended to limit the present disclosure, its application, or its use.

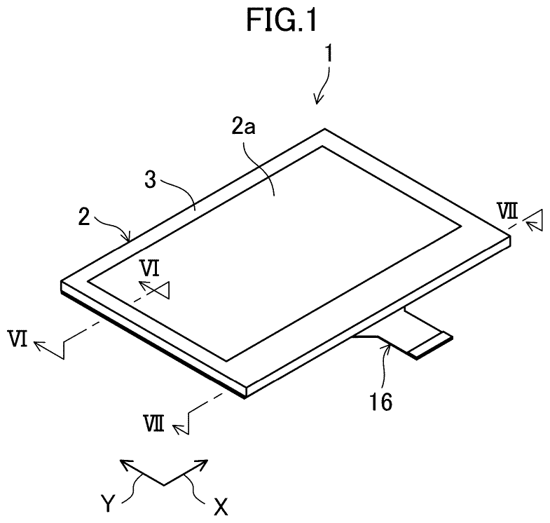

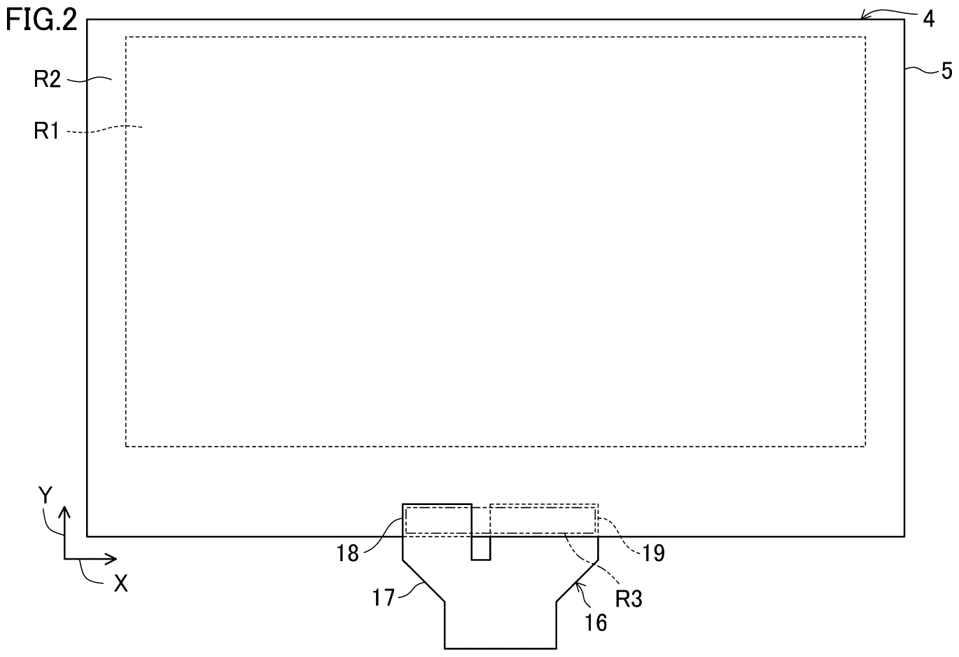

FIG. 1 shows the configuration of a touch sensor 1 to which a conductive film 4 (see FIGS. 2 to 5) according to an embodiment of the present disclosure is applied. The touch sensor 1 is a sensor input device on which a touch operation can be performed. The touch sensor 1 is used as an input device for, for example, an on-vehicle device such as a car navigation system, a display device of a personal computer, a mobile phone, a portable information terminal, a portable game machine, a copying machine, a ticket vending machine, an automatic teller machine, or a clock.

In the following description, an operation screen 2a of a cover member 2, which will be described later, is located on a “front side” of the touch sensor 1, whereas the opposite side thereof will be referred to as a “back side” of the touch sensor 1. With these terms, a positional relationship between elements forming the touch sensor 1 will be defined. Of a conductive film 4, a surface facing the back surface of the cover member 2 will be defined as a “front surface 5a”, and a surface located on the opposite side of the cover member 2 will be defined as a “back surface 5b”.

Further, in the present embodiment, for the sake of convenience in description, a first direction X extends from the left to the right in the plane of paper of FIGS. 1 to 3, whereas a second direction Y extends from the bottom to the top in the plane of paper of FIGS. 1 to 3.

### Cover Member

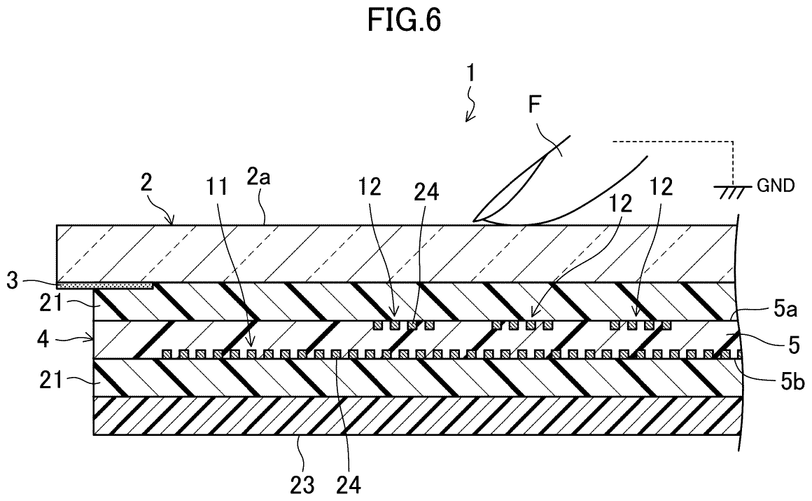

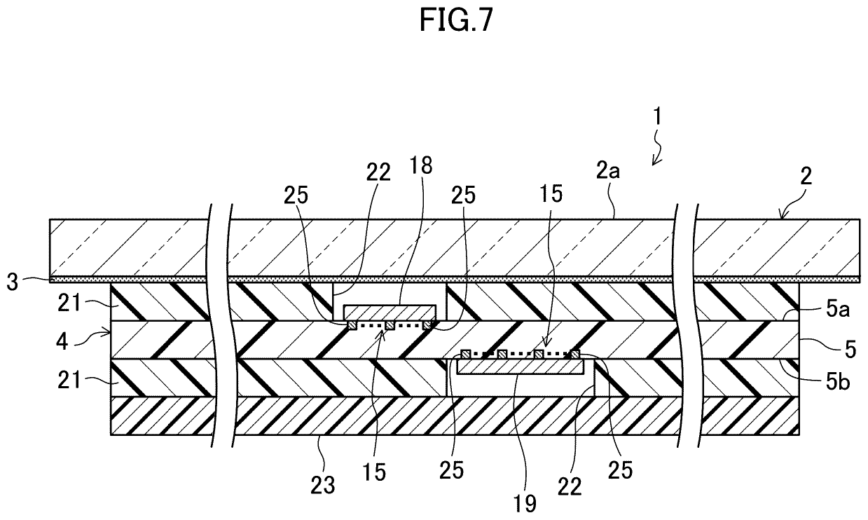

As shown in FIG. 1, the touch sensor 1 includes the cover member 2 having light-transmissive properties. The cover member 2 is a cover lens made of, for example, cover glass or plastic. The cover member 2 has, for example, a rectangular plate shape in a plan view. The cover member 2 is fixed to the front surface 5a of the conductive film 4 with an adhesive layer 21 described later (see FIGS. 6 and 7).

As shown in FIGS. 1, 6, and 7, a fringe 3 is provided on a peripheral edge portion of the back surface of the cover member 2. The fringe 3 is formed in a dark color such as black and in a substantially frame shape by, for example, screen printing. An inner rectangular region surrounded by the fringe 3 on the front surface of the cover member 2 is configured as the operation screen 2a with which a finger F (see FIG. 6) of a user or the like comes into contact in accordance with the touch operation.

### Conductive Film

As shown in FIG. 2, the conductive film 4 is formed in a substantially rectangular shape in a plan view. The conductive film 4 can be attached to the back surface side of the cover member 2 (see FIGS. 6 and 7). A specific configuration of the conductive film 4 will be described later.

As shown in FIGS. 2 to 4, the conductive film 4 is provided with a first region R1 and a second region R2.

The first region R1 is an inner region surrounded by the fringe 3 in a state in which the conductive film 4 is attached to the cover member 2. In this embodiment, the first region R1 is configured as a visible region of the touch sensor 1. Thus, the user of the touch sensor 1 can obtain visual information from a display panel (not shown) disposed on the back side of the touch sensor 1 via the first region R1.

The second region R2 is a region corresponding to the location of the fringe 3 in a state in which the conductive film 4 is attached to the cover member 2. That is, the second region R2 is a region located outside the first region R1. In this embodiment, the second region R2 is configured as an invisible region of the touch sensor 1. Thus, the user of the touch sensor 1 cannot visually recognize the components of the conductive film 4 located in the second region R2 from the outside.

### Adhesive Layer

As shown in FIGS. 6 and 7, the touch sensor 1 includes the adhesive layer 21. The adhesive layer 21 is stacked on each of the front surface 5a and back surface 5b of the conductive film 4. The adhesive layer 21 is made of an optical clear adhesive (OCA) having light-transmissive properties. The thickness of the adhesive layer 21 is preferably 25 μm to 250 μm.

As shown in FIG. 7, the adhesive layer 21 is partially cut out into a cutout 22. The cutout 22 located on the front surface 5a side corresponds to a location at which the front surface 5a and a front connection portion 18 described later are attached to each other. The cutout 22 located on the back surface 5b side corresponds to a location at which the back surface 5b and a back connection portion 19 described later are attached to each other.

### Transmission Electrode and Reception Electrode

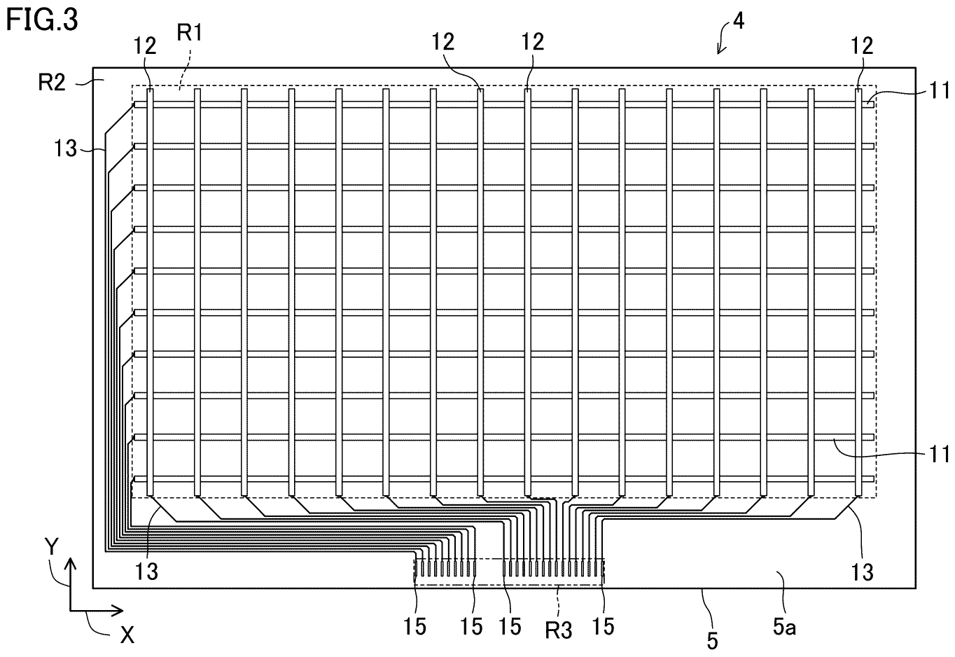

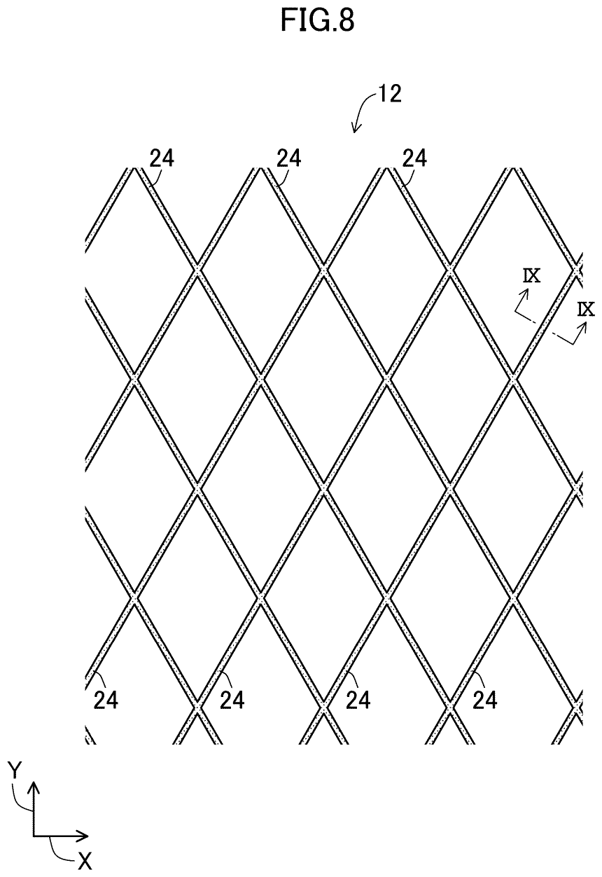

As shown in FIGS. 3 to 5, the touch sensor 1 includes a plurality of capacitive transmission electrodes 11 and reception electrodes 12. The plurality of transmission electrodes 11 and the plurality of reception electrodes 12 are disposed in the first region R1. Each of the transmission electrodes 11 and the reception electrodes 12 includes a plurality of first conductive lines 24 described later (see FIGS. 6 and 8).

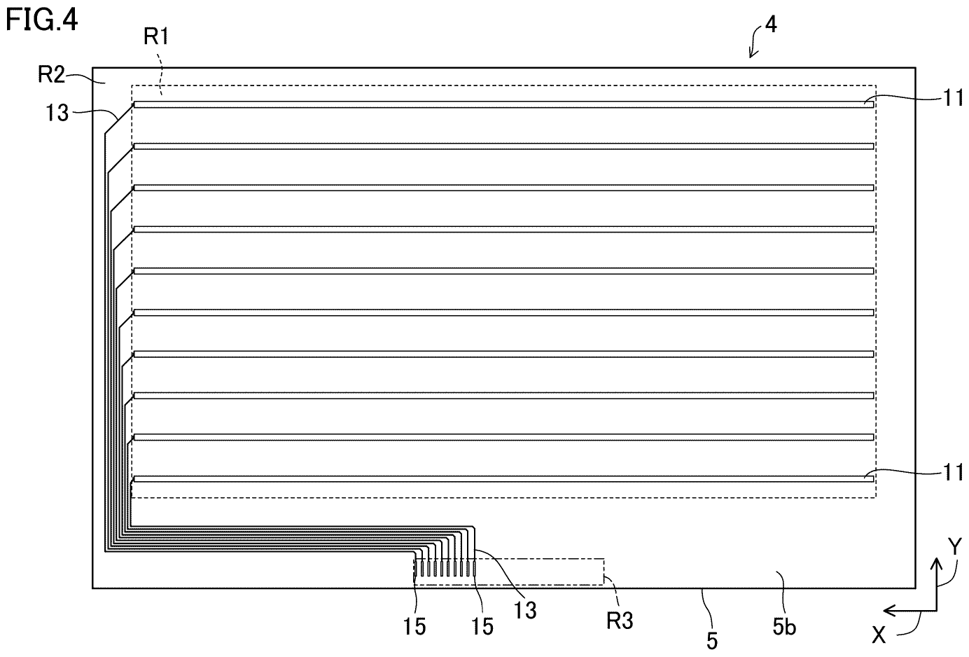

As shown in FIG. 4, each transmission electrode 11 is disposed on the back surface 5b. Each transmission electrode 11 extends in a substantially band shape along the first direction X in a plan view. The plurality of transmission electrodes 11 is disposed at intervals in the second direction Y. Each transmission electrode 11 is connected to a drive circuit (not shown) via a flexible wiring board 16 described later. This drive circuit allows each transmission electrode 11 to emit an electric field to therearound.

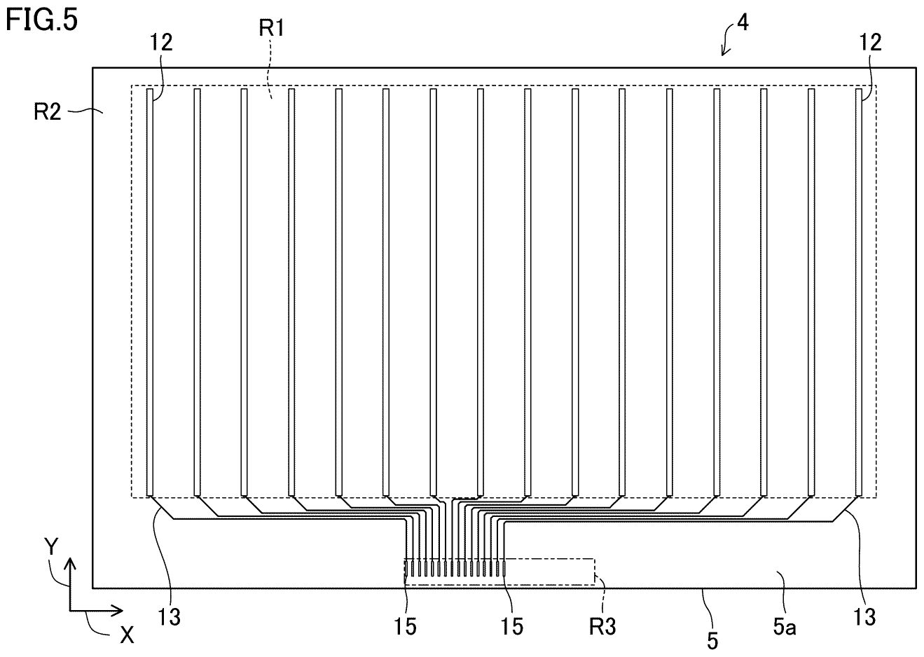

As shown in FIG. 5, each reception electrode 12 is disposed on the front surface 5a. Each reception electrode 12 is insulated from each transmission electrode 11 via a film base 6 (described later) of the conductive film 4. Each reception electrode 12 extends in a substantially band shape along the second direction Y in a plan view. The plurality of reception electrodes 12 is disposed at intervals in the first direction X.

As shown in FIG. 6, the touch sensor 1 can sense the touch operation with the user's finger F (i.e., detection target connected to the ground (GND)) in contact with the operation screen 2a via the plurality of transmission electrodes 11 and the plurality of reception electrodes 12.

The reception electrodes 12 receive the electric fields emitted from the transmission electrodes 11. Each reception electrode 12 is connected to a detection circuit (not shown) via the flexible wiring board 16 described later.

### Routing Wire

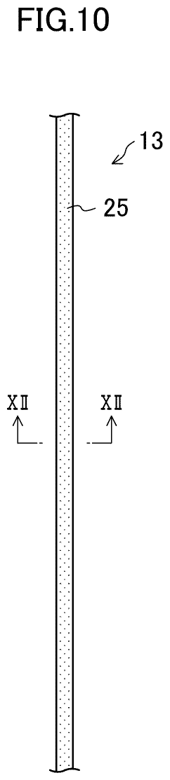

As shown in FIGS. 3 to 5, the touch sensor 1 includes a plurality of routing wires 13. The routing wire 13 is an element for electrically connecting the plurality of transmission electrodes 11 and the plurality of reception electrodes 12 to an external circuit (not shown). The plurality of routing wires 13 is disposed on each of the front surface 5a and the back surface 5b. Each routing wire 13 includes a plurality of second conductive lines 25 described later (see FIG. 10).

The plurality of routing wires 13 is disposed in the second region R2. Specifically, the plurality of routing wires 13 is disposed so as to overlap with the fringe 3 in a plan view from the operation screen 2a side. That is, the plurality of routing wires 13 cannot be visually recognized from the operation screen 2a side due to the fringe 3. In FIG. 6, the routing wires 13 are not shown for the sake of simplicity.

As shown in FIG. 4, one end portion of each routing wire 13 located on the back surface 5b is electrically connected to one end portion (end portion located on the left side in the plane of paper of FIG. 4) of each transmission electrode 11. The other end portions of the routing wires 13 are collected substantially at the center (connection region R3 described later) of the second region R2 of the conductive film 4 on the lower side in the plane of paper of FIG. 4.

As shown in FIG. 5, one end portion of each routing wire 13 located on the front surface 5a is electrically connected to one end portion (end portion located on the lower side in the plane of paper of FIG. 5) of each reception electrode 12. The other end portions of the routing wires 13 are collected substantially at the center (connection region R3 described later) of the second region R2 of the conductive film 4 on the lower side in the plane of paper of FIG. 5.

### Connection Pad

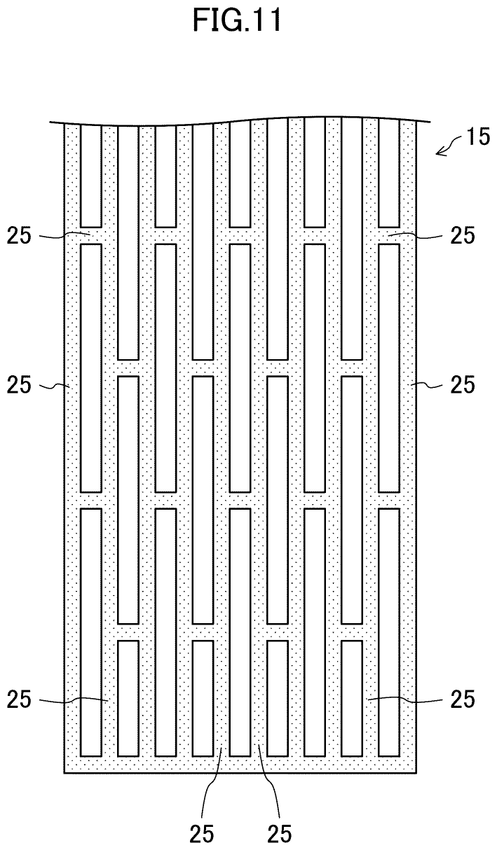

As shown in FIGS. 3 to 5, the touch sensor 1 includes a plurality of connection pads 15. Each connection pad 15 is provided at the other end portion of each routing wire 13. As shown in FIG. 7, the plurality of connection pads 15 is electrically connected to the flexible wiring board 16 (front connection portion 18 and back connection portion 19) described later. Each connection pad 15 includes a plurality of second conductive lines 25 described later (see FIGS. 7 and 11).

The plurality of connection pads 15 is disposed in the second region R2 (specifically, connection region R3 described later). Thus, the plurality of connection pads 15 cannot be visually recognized from the operation screen 2a side as in the plurality of routing wires 13.

### Flexible Wiring Board

As shown in FIG. 1, the touch sensor 1 includes the flexible wiring board 16. The flexible wiring board 16 has flexibility and electric properties unchanged even in a deformed state. The flexible wiring board 16 is formed of a flexible insulating film of, for example, polyimide (PI), polyethylene terephthalate (PET), or polyethylene naphthalate (PEN).

As shown in FIG. 2, the flexible wiring board 16 has a body 17, the front connection portion 18, and the back connection portion 19. The front connection portion 18 and the back connection portion 19 are formed integrally with the body 17. The front connection portion 18 and the back connection portion 19 are formed so as to branch in two directions from one end side of the body 17.

As shown in FIG. 7, the front connection portion 18 is fixed to a peripheral edge portion of the front surface 5a with an anisotropic conductive adhesive (not shown), for example. The front connection portion 18 is configured such that each of a plurality of terminals (not shown) provided on the front connection portion 18 is electrically connected to each of the plurality of connection pads 15 located on the front surface 5a.

The back connection portion 19 is fixed to a peripheral edge portion of the back surface 5b with the anisotropic conductive adhesive described above. The back connection portion 19 is configured such that each of a plurality of terminals (not shown) provided on the back connection portion 19 is electrically connected to each of the plurality of connection pads 15 located on the back surface 5b.

### Protective Film

As shown in FIGS. 6 and 7, the touch sensor 1 includes a protective film 23. The protective film 23 is a film material for mainly protecting the plurality of transmission electrodes 11 and the plurality of routing wires 13 located on the back surface 5b side. Examples of this film material include resin materials such as polyethylene terephthalate (PET), polycarbonate, cycloolefin polymer (COP), cycloolefin copolymer (COC), and PE.

The protective film 23 is substantially in a rectangular shape in a plan view, for example. The protective film 23 is formed with the same size as that of the conductive film 4. The protective film 23 is stacked at a location facing the back surface 5b. Specifically, the protective film 23 is fixed to the back surface 5b with the adhesive layer 21. The protective film 23 has a significantly higher adhesive strength than that of a process protective film (not shown) temporarily used in the course of manufacturing the touch sensor 1.

### Specific Configuration of Conductive Film

The conductive film 4 includes a substrate 5, the plurality of first conductive lines 24, and the plurality of second conductive lines 25.

### Substrate

As shown in FIGS. 2 to 5, the substrate 5 is formed in a substantially rectangular shape in a plan view. As shown in FIGS. 6 and 7, the substrate 5 is stacked such that the front surface 5a faces the back surface of the cover member 2 with the adhesive layer 21 interposed therebetween.

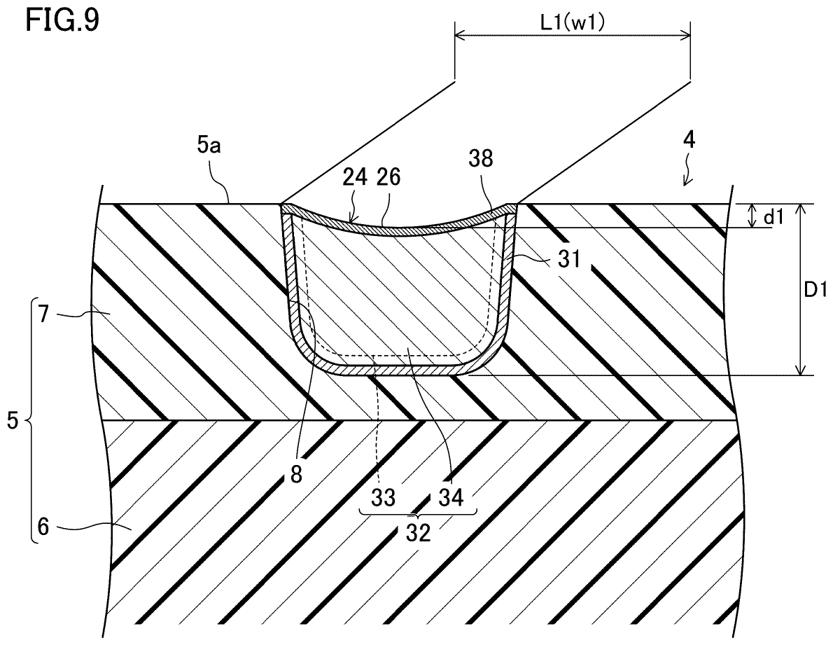

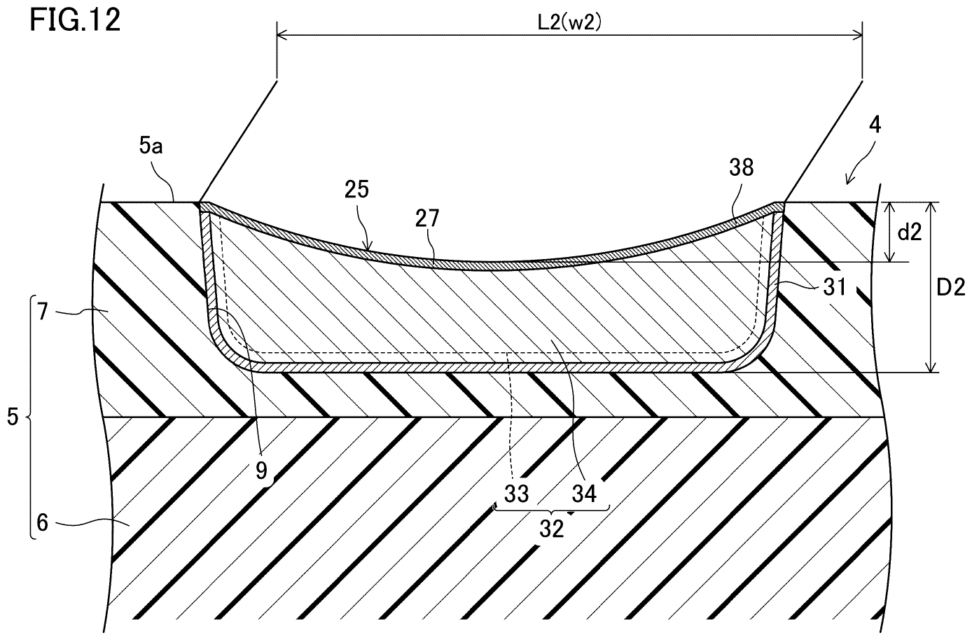

As shown in FIGS. 9 and 12, the substrate 5 has the film base 6. The film base 6 is made of a transparent resin material. Examples of this resin material include resin materials such as polyethylene terephthalate (PET), polycarbonate, cycloolefin polymer (COP), and cycloolefin copolymer (COC).

In this embodiment, the substrate 5 has two groove forming layers 7. Each groove forming layer 7 is a layer for forming a plurality of first grooves 8 and a plurality of second grooves 9 described later. Each groove forming layer 7 is made of a resin material having insulating properties and light-transmissive properties. The groove forming layer 7 has shaping properties for forming the groove, and also has a function of firmly bonding an adhesion layer 31 (described later) in the groove and the film base 6. The groove forming layer 7 is stacked on each of the front side and back side of the film base 6. The thickness of the groove forming layer 7 is, for example, 2.0 to 17.0 μm. In FIGS. 9 and 12, the groove forming layer 7 located on the back side of the film base 6 is not shown.

### First Groove

The plurality of first grooves 8 is provided on the front surface 5a side (see FIG. 9). The plurality of first grooves 8 is located in the first region R1. The plurality of first grooves 8 linearly extends in the front surface 5a to form a predetermined pattern described later. Although not shown, the plurality of first grooves 8 is also provided in the back surface 5b as in the front surface 5a side.

As shown in FIG. 9, the first groove 8 is formed in a bottomed shape recessed in the thickness direction of the substrate 5 (in a direction from the groove forming layer 7 toward the film base 6). The groove depth dimension D1 of the first groove 8 is set to, for example, 0.5 μm or more and 10.0 μm or less. More preferably, the groove depth dimension D1 of the first groove 8 is set to 0.5 μm or more and 2.0 μm or less.

The first groove 8 is configured to have a groove width dimension L1 of more than 0.3 μm and 30.0 μm or less. More preferably, the groove width dimension L1 of the first groove 8 is 0.5 μm or more and 3.0 μm or less.

In this embodiment, the plurality of first grooves 8 is configured such that the groove depth dimensions D1 thereof are substantially the same as each other. Moreover, the plurality of first grooves 8 is configured such that the groove width dimensions L1 thereof are substantially the same as each other.

In this embodiment, a corner between each side surface and the bottom of the first groove 8 is filleted. The corner is not necessarily filleted. The bottom surface of the first groove 8 may be curved. The side surfaces of the first groove 8 may be inclined such that the opening thereof gradually expands from the bottom of the first groove 8.

### Second Groove

The plurality of second grooves 9 is provided in the front surface 5a (see FIG. 12). The plurality of second grooves 9 is located in the second region R2. The plurality of second grooves 9 linearly extends in the front surface 5a to form a predetermined pattern described later. Although not shown, the plurality of second grooves 9 is also provided in the back surface 5b as in the front surface 5a side.

As shown in FIG. 12, the second groove 9 is formed in a bottomed shape recessed in the thickness direction of the substrate 5 (in the direction from the groove forming layer 7 toward the film base 6). The groove depth dimension D2 of the second groove 9 is set to, for example, 0.5 μm or more and 10.0 μm or less. More preferably, the groove depth dimension D2 of the second groove 9 is set to 0.5 μm or more and 2.0 μm or less.

The second groove 9 is configured to have a groove width dimension L2 of more than 0.3 μm and 30.0 μm or less. More preferably, the groove width dimension L2 of the second groove 9 is 8.0 μm or more and 12.0 μm or less. The groove width dimension L2 of the second groove 9 is configured to be greater than the groove width dimension L1 of the first groove 8.

In this embodiment, the plurality of second grooves 9 is configured such that the groove depth dimensions D2 thereof are substantially the same as each other. Moreover, the plurality of second grooves 9 is configured such that the groove width dimensions L2 thereof are substantially the same as each other.

In this embodiment, a corner between each side surface and the bottom of the second groove 9 is filleted. The corner is not necessarily filleted. The side surfaces of the second groove 9 may be inclined such that the opening thereof gradually expands from the bottom of the second groove 9.

### First Conductive Line

FIG. 8 shows, as an example, the plurality of first conductive lines 24 forming each reception electrode 12. The plurality of first conductive lines 24 is disposed in a predetermined pattern on the front surface 5a. As an example of the predetermined pattern, as shown in FIG. 8, a first pattern (mesh pattern) in which the plurality of first conductive lines 24 is disposed in a mesh shape is employed. Although not shown, the plurality of first conductive lines 24 for forming each transmission electrode 11 is also disposed in the predetermined pattern on the back surface 5b.

In the first pattern, the plurality of first conductive lines 24 intersects each other and is disposed at predetermined intervals (equal intervals in the shown example). Each first conductive line 24 forming the first pattern extends obliquely from both the first direction X and the second direction Y. The first pattern is a mesh structure in which a plurality of cells formed by the plurality of first conductive lines 24 is regularly arranged. Each cell has, for example, a rhombic shape.

The predetermined pattern is not limited to the first pattern (i.e., mesh pattern), and may be, for example, a second pattern obtained by disposing the plurality of first conductive lines 24 in a ladder shape, or a third pattern obtained by disposing the plurality of first conductive lines 24 in a shape other than the mesh shape and the ladder shape.

The line width of the first conductive line 24 is set to, for example, 0.5 μm or more and 3.0 μm or less. That is, the line width of the first conductive line 24 is the same as the groove width dimension L1 of each first groove 8. Moreover, in this embodiment, the plurality of first conductive lines 24 is configured such that the line widths thereof are substantially the same as each other.

The surface roughness of a portion of the first conductive line 24 exposed from the groove forming layer 7 is set to, for example, 0.01 μm or more and 0.34 μm or less. When the surface roughness of the first conductive line 24 is set to the above-described numerical range, reflection (specular reflection) of external light, such as sunlight or illumination light, having entered through the operation screen 2a of the touch sensor 1 on the surface of the first conductive line 24 is reduced. As a result, the plurality of first conductive lines 24 forming the transmission electrodes 11 and the reception electrodes 12 are less likely to be visually recognized from the operation screen 2a side when viewed by the user of the touch sensor 1 from the operation screen 2a side. That is, so-called “visible lines” of the plurality of first conductive lines 24 are reduced. Accordingly, the appearance of the touch sensor 1 can be improved. Further, when the surface roughness of the first conductive line 24 is set to the above-described numerical range, the surface of the first conductive line 24 is less likely to contact the adhesive layer 21. As a result, the conduction reliability of the first conductive line 24 is easily ensured.

### Sectional Structure of First Conductive Line

As shown in FIG. 9, the first conductive line 24 includes the adhesion layer 31, a conductive layer 32, and a blackened layer 38.

The adhesion layer 31 is an element for ensuring the adhesiveness of the conductive layer 32 to the first groove 8. In addition, the adhesion layer 31 functions to make the first conductive line 24 less visible by the user from the operation screen 2a side of the touch sensor 1.

The adhesion layer 31 is a metal layer made of a metal nitride or a metal oxide containing at least one metal selected from a group consisting of Ti, Al, V, W, Ta, Si, Cr, Ag, Mo, Cu, and Zn, for example. The adhesion layer 31 may be a single layer or a stack of a plurality of layers with different compositions. The adhesion layer 31 is stacked as a thin film on the first groove 8 by vapor deposition or sputtering, for example.

The conductive layer 32 is an element for ensuring the conductivity of the first conductive line 24. The conductive layer 32 is embedded in the first groove 8. The conductive layer 32 includes a seed layer 33 and a body layer 34. Both the seed layer 33 and the body layer 34 are made of conductive materials. Suitable as the conductive material is a conductive metal such as copper (Cu) or silver (Ag). The conductive metal may be replaced with, for example, a transparent conductive material with light-transmissive properties, such as a conductive resin material, an indium tin oxide, or a tin oxide.

The seed layer 33 functions to improve the adhesiveness between the adhesion layer 31 and the body layer 34. Specifically, the seed layer 33 functions as a cathode for depositing a plating solution such as copper (Cu) on the adhesion layer 31, for example, in electroplating for forming the body layer 34. The seed layer 33 is stacked as a thin film on the adhesion layer 31 by vapor deposition or sputtering, for example. If the body layer 34 is formed by a method other than the electroplating, no seed layer 33 may be provided.

The body layer 34 is formed by vapor deposition, sputtering, electroless plating, or electroplating, for example. In this embodiment, the body layer 34 is stacked on the seed layer 33 by electroplating. After the electroplating, the seed layer 33 and the body layer 34 are integrally formed such that an interface between the seed layer 33 and the body layer 34 is invisible.

The blackened layer 38 is stacked on the conductive layer 32 on the opening side of a first recess 26 described later. The thickness of the blackened layer 38 is, for example, 7 nm to 40 nm. The blackened layer 38 functions to make the first conductive line 24 less visible by the user of the touch sensor 1 from the operation screen 2a side.

The blackened layer 38 is formed by crystal grains of copper being substituted with palladium (by blackening), where the crystal grains of copper are located at boundaries (so-called “grain boundaries”) between the crystal grains of copper located in the surface of the conductive layer 32 (body layer 34). Specifically, in the blackening, grain boundary corrosion progresses along the boundaries (grain boundaries) between the crystal grains of copper located in the surface of the body layer 34, and the crystal grains of copper forming the surface of the body layer 34 are substituted with palladium. The blackened layer 38 is stacked on the surface of the body layer 34 in this manner.

### First Recess

As shown in FIG. 9, the first conductive line 24 has the first recess 26. The first recess 26 is in a bottomed shape recessed from the opening side of the first groove 8 in the thickness direction of the substrate 5 in a cross section. The first recess 26 is formed in a curved shape having a predetermined radius of curvature. The longitudinal direction of the first recess 26 extends along the extending direction of the first groove 8. The above-described term “curved” means a shape curved in a bow shape, and the concept of the term “curved” includes an “arc shape”.

In this embodiment, the recess width dimension w1 of the first recess 26 is substantially the same as the groove width dimension L1 of the first groove 8. Preferably, the first recess 26 is configured such that the recess depth dimension d1 thereof is 0.004 μm or more and 7.0 μm or less. Moreover, the first groove 8 and the first recess 26 are configured such that a value obtained by dividing the recess depth dimension dl by the groove width dimension L1 is 0.01 or more and 0.4 or less. The recess depth dimension d1 is a length from the front surface 5a (or the back surface 5b) to a location corresponding to the deepest portion of the first recess 26.

### Second Conductive Line

FIG. 10 shows, as an example, the second conductive line 25 forming each routing wire 13. As shown in FIG. 10, each routing wire 13 of this embodiment includes one second conductive line 25.

FIG. 11 shows, as an example, the plurality of second conductive lines 25 forming each connection pad 15. Each connection pad 15 is formed in a pattern (corresponding to the second pattern described above) in which the plurality of second conductive lines 25 is disposed in the ladder shape.

The line width of each second conductive line 25 is set to, for example, 8.0 μm or more and 12.0 μm or less. That is, the line width of the second conductive line 25 is the same as the groove width dimension L2 of each second groove 9. Moreover, in this embodiment, the plurality of second conductive lines 25 is configured such that the line widths thereof are substantially the same as each other.

The surface roughness of the second conductive line 25 is set to, for example, 0.01 μm or more and 0.34 μm or less. When the surface roughness of the second conductive line 25 is set to the above-described numerical range, the surface of the second conductive line 25 is less likely to contact the adhesive layer 21. As a result, the conduction reliability of the second conductive line 25 is easily ensured.

### Sectional Structure of Second Conductive Line

As shown in FIG. 12, the second conductive line 25 includes the adhesion layer 31, the conductive layer 32, and the blackened layer 38. The adhesion layer 31, the conductive layer 32, and the blackened layer 38 forming the second conductive line 25 are the same as the adhesion layer 31, the conductive layer 32, and the blackened layer 38 forming the first conductive line 24, and therefore, detailed description thereof will be omitted.

### Second Recess

As shown in FIG. 12, the second conductive line 25 has a second recess 27. The second recess 27 is in a bottomed shape recessed from the opening side of the second groove 9 in the thickness direction of the substrate 5 in a cross section. The second recess 27 is formed in a curved shape having a predetermined radius of curvature. The longitudinal direction of the second recess 27 extends along the extending direction of the second groove 9.

In this embodiment, the recess width dimension w2 of the second recess 27 is substantially the same as the groove width dimension L2 of the second groove 9. Preferably, the second recess 27 is configured such that the recess depth dimension d2 thereof is 0.004 μm or more and 7.0 μm or less. Moreover, the second groove 9 and the second recess 27 are configured such that a value obtained by dividing the recess depth dimension d2 by the groove width dimension L2 is 0.01 or more and 0.4 or less. The recess depth dimension d2 is a length from the front surface 5a (or the back surface 5b) to a location corresponding to the deepest portion of the second recess 27.

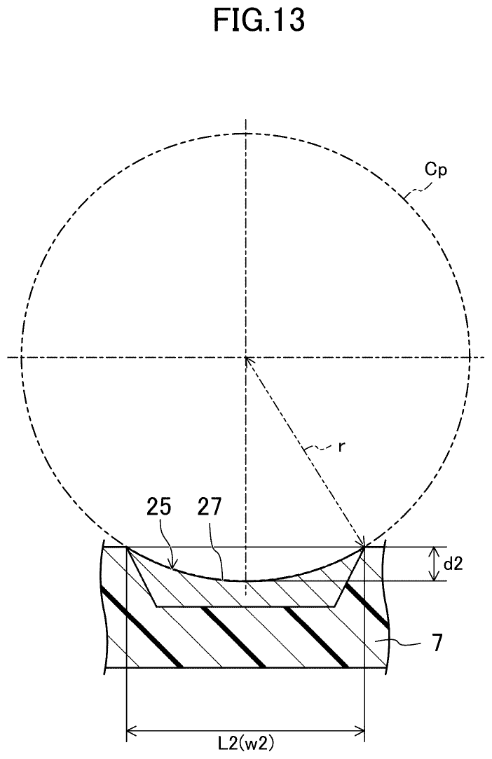

As shown in FIGS. 2 to 4, the second region R2 includes the connection region R3 where an anisotropic conductive resin material containing a plurality of conductive particles Cp (see FIG. 13) can be disposed on the surface of the substrate 5. The second groove 9 is configured such that part of the second groove 9 is located in the connection region R3. In this embodiment, the particle size (radius r shown in FIG. 13) of the conductive particle Cp is assumed to be in a range of 3.0 μm to 20.0 μm.

As shown in FIG. 13, the second conductive line 25 is configured such that the second recess 27 located in the connection region R3 has such a size that the second recess 27 can contact the conductive particle Cp. Specifically, the second recess 27 located in the connection region R3 is configured such that the cross-sectional shape of the outer surface of the second recess 27 is curved.

In this embodiment, the second recess 27 located in the connection region R3 is configured such that the cross-sectional shape of the outer surface of the second recess 27 is an arc shape. Preferably, the second recess 27 located in the connection region R3 is configured such that the radius of curvature of the arc shape is the same as the radius of curvature, i.e., the particle size (radius r shown in FIG. 13), of the conductive particle Cp.

More preferably, the second recess 27 located in the connection region R3 is configured such that the radius of curvature of the arc shape is greater than the radius of curvature, i.e., the particle size (radius r shown in FIG. 13), of the conductive particle Cp.

Here, the recess depth dimension d2 of the second recess 27 is preferably configured to satisfy the following relational expression in a relationship between the particle size (radius r) of the conductive particle Cp and the groove width dimension L2 of the second groove 9.

### [Expression 1]

d2=r−\sqrt{r²−(L2/2)²}

### Characteristic Configuration

As shown in FIGS. 9 and 12, as a characteristic configuration according to the embodiment of the present disclosure, the second recess 27 is configured to be more recessed than the first recess 26. Specifically, the first recess 26 and the second recess 27 are configured such that the recess width dimension w2 of the second recess 27 is greater than the recess width dimension w1 of the first recess 26. Further, the first recess 26 and the second recess 27 are configured such that the recess depth dimension d2 of the second recess 27 is greater than the recess depth dimension d1 of the first recess 26.

### [Advantageous Effects of Embodiment]

As described above, the first conductive line 24 disposed in the first region R1 has the first recess 26. Thus, when external light (sunlight, illumination light, or the like) having entered the touch sensor 1 from the operation screen 2a side of the touch sensor 1 enters the first recess 26, the external light is reflected (diffusely reflected) in various directions in the first recess 26. That is, the external light having entered the first recess 26 is less likely to be specularly reflected toward the outside of the touch sensor 1 due to the diffuse reflection. This reduces the reflectance of the first conductive line 24 at the specular reflection of the external light. As a result, the so-called “visible lines” of the plurality of first conductive lines 24 are reduced. Specifically, in this embodiment, when the user views the touch sensor 1 from the operation screen 2a side, the components (particularly, the first pattern forming each reception electrode 12 disposed on the operation screen 2a side) of the conductive film 4 located in the first region R1 are less likely to be visually recognized. This improves the visibility of the first region R1.

The first recess 26 is recessed from the opening side of the first groove 8 in the thickness direction of the substrate 5 in a cross section. Moreover, the second recess 27 is also recessed from the opening side of the second groove 9 in the thickness direction of the substrate 5 in a cross section. Thus, for example, even in a case where the above-described process protective film is repeatedly attached to the conductive film 4 or the process protective film is repeatedly detached from the conductive film 4 in the course of manufacturing the touch sensor 1, part of the conductive layer 32 forming each of the first conductive lines 24 and the second conductive lines 25 is less likely to be detached from each of the first grooves 8 and the second grooves 9 together with an adhesive portion of the process protective film. This makes the conductive layer 32 less likely to corrode, or makes it possible to prevent damage to the conductive layer 32 due to ESD breakdown in advance. That is, the states of the first conductive line 24 and the second conductive line 25 are properly maintained, and the conduction reliability of the first conductive line 24 and the second conductive line 25 is ensured.

Further, the first recess 26 and the second recess 27 are configured such that the recess width dimension w2 of the second recess 27 is greater than the recess width dimension w1 of the first recess 26 and the recess depth dimension d2 of the second recess 27 is greater than the recess depth dimension d1 of the first recess 26. That is, the second recess 27 is configured to be more recessed than the first recess 26. According to such a configuration, for example, in the connection region R3 located in the second region R2, the conductive particle Cp contained in the anisotropic conductive resin material is easily fitted in the second recess 27. That is, the area of contact between the conductive particle Cp and the surface of the second recess 27 increases. As a result, an electrical connection state between the second conductive line 25 and the conductive particle Cp is easily stabilized, and the conduction reliability of the second conductive line 25 located in the second region R2 is improved.

Thus, in the conductive film 4 according to the embodiment of the present disclosure and the touch sensor 1 including the conductive film 4, the visibility of the first region R1 can be improved, and the conduction reliability of the first conductive line 24 and the second conductive line 25 can be ensured.

Preferably, the groove width dimension L1 of the first groove 8 is set to 0.5 μm or more and 3.0 μm or less, and the groove depth dimension D1 of the first groove 8 is set to 0.5 μm or more and 2.0 μm or less. With these settings, the first conductive line 24 is reduced in thickness. This reduces the so-called “visible lines” of the plurality of first conductive lines 24 and improves the visibility of the first region R1. Preferably, the groove width dimension L2 of the second groove 9 is set to 8.0 μm or more and 12.0 μm or less, and the groove depth dimension D2 of the second groove 9 is set to 0.5 μm or more and 2.0 μm or less. With these settings, the line width of the second conductive line 25 is relatively increased. This easily stabilizes the electrical connection state between the second conductive line 25 and the conductive particle Cp. That is, the conduction reliability of the second conductive line 25 located in the second region R2 is ensured. Thus, the visibility of the first region R1 can be improved, and the conduction reliability of the second conductive line 25 can be particularly ensured.

In a case where the groove depth dimensions D1, D2 are set to 0.5 μm or more and 2.0 μm or less, the recess depth dimensions d1, d2 may be set to appropriate dimensions corresponding to the groove depth dimensions D1, D2. For example, in a case where each of the groove depth dimensions D1, D2 is set to 2.0 μm which is the upper limit of the above-described numerical range, each of the recess depth dimensions d1, d2 may be set to about 0.15 μm or more and 1.34 μm or less.

Preferably, the first recess 26 and the second recess 27 are configured such that the recess depth dimensions d1, d2 thereof are 0.004 μm or more and 7.0 μm or less. According to such a configuration, the external light having entered the first recess 26 is less likely to be specularly reflected toward the outside of the touch sensor 1 due to the diffuse reflection, and therefore, the visibility of the first region R1 is improved, similarly to the above-described advantageous effect. In addition, the first recess 26 and the second recess 27 are less likely to contact the adhesive portion of the above-described process protective film. Thus, similarly to the above-described advantageous effect, the conduction reliability of the first conductive line 24 and the second conductive line 25 is ensured.

In a case where the recess depth dimensions d1, d2 are set to 0.004 μm or more and 7.0 μm or less, the groove depth dimensions D1, D2 may be set to appropriate dimensions corresponding to the recess depth dimensions d1, d2. For example, in a case where each of the recess depth dimensions d1, d2 is set to 7.0 μm which is the upper limit of the above-described numerical range, each of the groove depth dimensions D1, D2 may be set to about 10.0 μm.

The second groove 9 and the second recess 27 are configured such that the value obtained by dividing the recess depth dimension d2 by the groove width dimension L2 is 0.01 or more and 0.4 or less. With such a relationship, for example, in the connection region R3 located in the second region R2, the conductive particle Cp contained in the anisotropic conductive resin material is easily fitted in the second recess 27. More specifically, the conductive particle Cp easily comes into contact with the surface of the second recess 27. As a result, the electrical connection state between the second conductive line 25 and the conductive particle Cp is easily stabilized. Thus, the conduction reliability of the second conductive line 25 located in the second region R2 can be improved.

The second region R2 includes the connection region R3 where the anisotropic conductive resin material containing the plurality of conductive particles Cp can be disposed on the surface of the substrate 5, and the second groove 9 is configured such that part thereof is located in the connection region R3. The second conductive line 25 is configured such that the second recess 27 located in the connection region R3 has such a size that the second recess 27 can contact each of the plurality of conductive particles Cp. According to such a configuration, in the connection region R3, the conductive particle Cp contained in the anisotropic conductive resin material is easily fitted in the second recess 27. As a result, the electrical connection state between the second conductive line 25 and the conductive particle Cp is easily stabilized. Thus, the conduction reliability of the second conductive line 25 located in the second region R2 can be improved.

The second recess 27 located in the connection region R3 is configured such that the cross-sectional shape of the outer surface of the second recess 27 is curved. According to such a configuration, the conductive particle Cp substantially in a spherical shape is easily fitted in the second recess 27. As a result, the electrical connection state between the second conductive line 25 and the conductive particle Cp is easily stabilized. Thus, the conduction reliability of the second conductive line 25 located in the second region R2 can be improved.

The second recess 27 located in the connection region R3 is configured such that the cross-sectional shape of the outer surface of the second recess 27 is in the arc shape, and the second recess 27 located in the connection region R3 is configured such that the radius of curvature of the arc shape is greater than the radius of curvature, i.e., the particle size, of the conductive particle Cp. According to such a configuration, the conductive particle Cp is easily fitted in the second recess 27, and the conductive particle Cp easily contacts the outer surface of the second recess 27. As a result, the electrical connection state between the second conductive line 25 and the conductive particle Cp is easily stabilized. Thus, the conduction reliability of the second conductive line 25 located in the second region R2 can be further improved.

The first conductive line 24 further includes the blackened layer 38. The blackened layer 38 makes the first conductive line 24 less visible by the user of the touch sensor 1 from the operation screen 2a side. As a result, the visibility of the first region R1 can be improved.

### [First Variation of Embodiment]

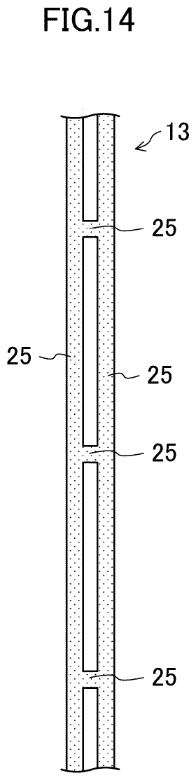

While each routing wire 13 includes one second conductive line 25 in the embodiment described above, the configuration is not limited thereto. For example, as in a first variation shown in FIG. 14, each routing wire 13 may include a plurality of second conductive lines 25. FIG. 14 shows, as an example, the routing wire 13 in a pattern in which the plurality of second conductive lines 25 is disposed in the ladder shape.

### [Second Variation of Embodiment]

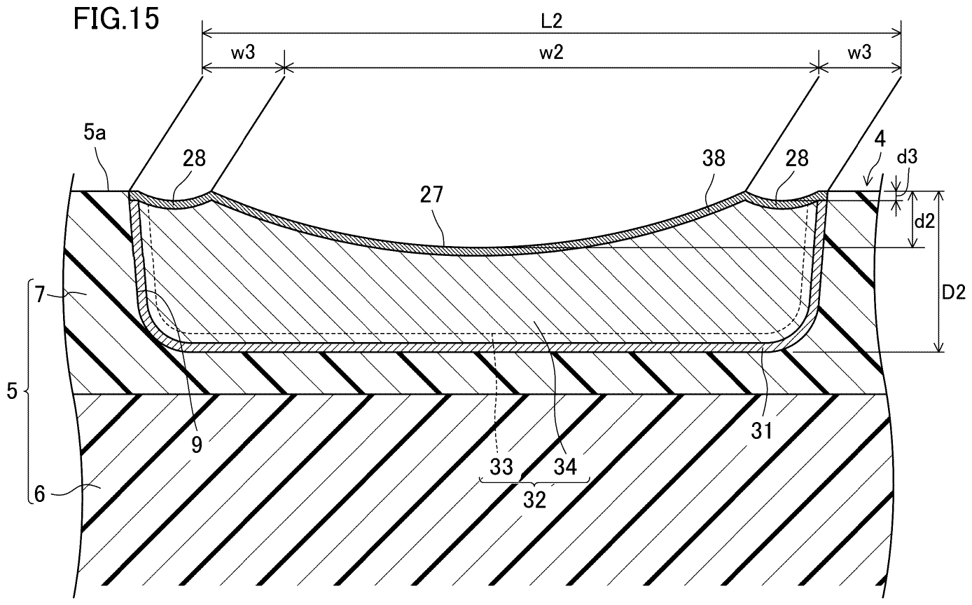

While only one second recess 27 is provided in the second conductive line 25 in the embodiment described above, the configuration is not limited thereto. For example, as in a second variation shown in FIG. 15, the second conductive line 25 may have one second recess 27 and two third recesses 28.

As shown in FIG. 15, the second conductive line 25 of the second variation is configured such that the recess width dimension w2 of the second recess 27 is less than the groove width dimension L2 of the second groove 9. The second groove 9 of this variation is configured to have a groove width dimension L2 of more than 0.3 μm and 30.0 μm or less, as in the embodiment described above. Moreover, the second recess 27 of this variation is configured such that the recess depth dimension d2 thereof is 0.004 μm or more and 7.0 μm or less, as in the embodiment described above.

The third recesses 28 are disposed on both sides of the second recess 27. The recess width dimension w3 of the third recess 28 is less than the recess width dimension w3 of the second recess 27. The recess depth dimension d3 of the third recess 28 is less than the recess depth dimension d3 of the second recess 27.

In such a variation, the second conductive line 25 is less susceptible to the adhesive layer 21 in the course of manufacturing the touch sensor 1 due to the second recess 27 and the third recesses 28, 28. This makes the conductive layer 32 less likely to corrode, or makes it possible to prevent damage to the conductive layer 32 due to the ESD breakdown in advance. Thus, the state of the second conductive line 25 is properly maintained, and the conduction reliability of the second conductive line 25 is ensured.

In this variation, the second recess 27 has a proper size. Thus, as in the embodiment described above, the electrical connection state between the second conductive line 25 and the conductive particle Cp is easily stabilized, and the conduction reliability of the second conductive line 25 located in the second region R2 is improved.

Although not shown, the first conductive line 24 may also have the first recess 26 and at least one third recess 28. With this configuration, the conduction reliability of the second conductive line 25 is also ensured. Further, in a case where the first conductive line 24 has the first recess 26 and at least one third recess 28, the external light having entered the first recess 26 and the third recess 28 is diffusely reflected, and therefore, the reflectance of the first conductive line 24 at the specular reflection of the external light is further reduced. As a result, the visibility of the first region R1 is improved.

### [Other Embodiments]

In the embodiment and the variations above, the touch sensor 1 to which the conductive film 4 according to the embodiment of the present disclosure is applied has been described as an example, but the present disclosure is not limited thereto. For example, the conductive film 4 according to the embodiment of the present disclosure can be widely applied to technical fields other than the touch sensor 1 (for example, various technical fields such as a liquid crystal display device, an organic electroluminescent display device (OLED), a micro LED display device, a solar cell device, a heater device, an antenna device, and an electromagnetic wave shielding sheet).

While the single substrate 5 is used for the conductive film 4 in the embodiment described above, the configuration is not limited thereto. For example, the substrate 5 may be a laminate (not shown) obtained by bonding two bases.

While the plurality of transmission electrodes 11 and the plurality of reception electrodes 12 are formed on both surfaces (front surface 5a and back surface 5b) of the single substrate 5 in the conductive film 4 according to the embodiment described above, the configuration is not limited thereto. That is, the plurality of transmission electrodes 11 and the plurality of reception electrodes 12 may be formed on only one surface (any one of the front surface 5a or the back surface 5b) of the single substrate 5.

While each of the transmission electrode 11 and the reception electrode 12 is substantially in the band shape in the embodiment described above, the configuration is not limited thereto. For example, an intermediate portion of each reception electrode 12 may protrude to taper in the first direction X or the opposite direction thereof into protrusions (not shown) repeated in the extending direction. Similarly, each transmission electrode 11 may have the following shape in place of the substantially band shape in the embodiment described above. An intermediate portion thereof may protrude to taper in the second direction Y or the opposite direction thereof into protrusions (not shown) repeated in the extending direction. In other words, each electrode may be formed into a shape with pads in a rhombic shape, for example, repeated in the extending direction.

While the conductive film 4 according to the embodiment described above includes the groove forming layers 7, 7 formed on both surfaces of the film base 6, the configuration is not limited thereto. That is, the configuration may be such that no groove forming layers 7 are stacked on the film base 6 (i.e., the configuration only with the film base 6). In such a configuration, the plurality of first grooves 8 and the plurality of second grooves 9 may be formed in both surfaces of the film base 6.

While the plurality of first grooves 8 is configured such that the groove depth dimensions D1 thereof are substantially the same as each other in the embodiment described above, the configuration is not limited thereto. For example, the plurality of first grooves 8 may be configured to have different groove depth dimensions D1.

While the plurality of second grooves 9 is configured such that the groove depth dimensions D2 thereof are substantially the same as each other in the embodiment described above, the configuration is not limited thereto. For example, the plurality of second grooves 9 may be configured to have different groove depth dimensions D2.

While the plurality of first grooves 8 is configured such that the groove width dimensions L1 thereof are substantially the same as each other in the embodiment described above, the configuration is not limited thereto. For example, the plurality of first grooves 8 may be configured such that the groove width dimensions L1 thereof are different from each other in the above-described range of 0.5 μm or more and 3.0 μm or less. According to such a configuration, the plurality of first conductive lines 24 is configured to have different line widths. That is, the plurality of first conductive lines 24 may be configured such that the line widths thereof are different from each other within the range in which the visibility of the first region R1 is ensured. Further, the conductive film 4 having the configuration in which the line widths of the plurality of first conductive lines 24 are different from each other can also be applied to the above-described technical fields other than the touch sensor 1.

While the plurality of first grooves 8 is configured such that the groove width dimensions L1 thereof are substantially the same as each other in the embodiment described above, the configuration is not limited thereto. For example, the plurality of first grooves 8 may be configured such that the groove width dimension L1 of one of these first grooves 8 varies in the above-described range of 0.5 μm or more and 3.0 μm or less. According to such a configuration, the plurality of first conductive lines 24 is configured such that the line width of one of the plurality of first grooves 8 varies. That is, the plurality of first conductive lines 24 may be configured such that the line widths thereof are within the range in which the visibility of the first region R1 is ensured. Further, the conductive film 4 having the configuration in which the line widths of the plurality of first conductive lines 24 are different from each other can also be applied to the above-described technical fields other than the touch sensor 1.

While the plurality of second grooves 9 is configured such that the groove width dimensions L2 thereof are substantially the same as each other in the embodiment described above, the configuration is not limited thereto. For example, the plurality of second grooves 9 may be configured such that the groove width dimensions L2 thereof are different from each other in the above-described range of 8.0 μm or more and 12.0 μm or less. According to such a configuration, the plurality of second conductive lines 25 is configured to have different line widths. That is, the plurality of second conductive lines 25 may be configured such that the line widths thereof are different from each other within the range in which the conduction reliability of each second conductive line 25 is ensured. Further, the conductive film 4 having the configuration in which the line widths of the plurality of second conductive lines 25 are different from each other can also be applied to the above-described technical fields other than the touch sensor 1.

While the plurality of second grooves 9 is configured such that the groove width dimensions L2 thereof are substantially the same as each other in the embodiment described above, the configuration is not limited thereto. For example, the plurality of second grooves 9 may be configured such that the groove width dimension L2 of one of these second grooves 9 varies in the above-described range of 8.0 μm or more and 12.0 μm or less. According to such a configuration, the plurality of second conductive lines 25 is configured such that the line width of one of the plurality of second grooves 9 varies. That is, the plurality of second conductive lines 25 may be configured such that the line widths thereof are within the range in which the conduction reliability of each second conductive line 25 is ensured. Further, the conductive film 4 having the configuration in which the line widths of the plurality of second conductive lines 25 are different from each other can also be applied to the above-described technical fields other than the touch sensor 1.

While the entire outer surface of each of the first recess 26 and the second recess 27 is curved in a cross section in the conductive film 4 in the embodiment described above, the configuration is not limited thereto. That is, each of the first recess 26 and the second recess 27 is not necessarily formed such that the entire outer surface thereof is curved. For example, although not shown, only part of the outer surface of each of the first recess 26 and the second recess 27 may be curved (or formed in the arc shape). Alternatively, each of the first recess 26 and the second recess 27 may be formed such that the entire outer surface thereof is substantially in a V-shape in a cross section.

While the adhesion layer 31 is formed in each of the first groove 8 and the second groove 9 in the conductive film 4 in the embodiment described above, the configuration is not limited thereto. That is, the conductive layer 32 may be directly formed in each of the first groove 8 and the second groove 9 without the adhesion layer 31.

While the blackened layer 38 is provided in the conductive film 4 in the embodiment described above, the blackened layer 38 is not necessarily provided.

While the conductive film 4 includes the plurality of first conductive lines 24 and the plurality of second conductive lines 25 in the embodiment described above, the configuration is not limited thereto. For example, in a case where the conductive film 4 is applied to a technical field other than the touch sensor 1, the conductive film 4 may have a form (not shown) including at least one first conductive line 24 and at least one second conductive line 25. That is, the conductive film 4 may have a form in which at least one first groove 8 is located in the first region R1 and at least one second groove 9 is located in the second region R2.

While the embodiments of the present disclosure have been described above, the present disclosure is not limited thereto and various modifications can be made within the scope of the present disclosure.

### INDUSTRIAL APPLICABILITY

The present disclosure is industrially applicable as a conductive film applicable to a touch sensor or the like.

### DESCRIPTION OF REFERENCE CHARACTERS

1 Touch Sensor
2 Cover Member
2a Operation Screen
3 Fringe
4 Conductive Film
5 Substrate
6 Film Base
7 Groove Forming Layer
8 First Groove
9 Second Groove
11 Transmission Electrode
12 Reception Electrode
13 Routing Wire
15 Connection Pad
16 Flexible Wiring Board
17 Flexible Wiring Board Body
18 Flexible Wiring Board Front Connection Portion
19 Flexible Wiring Board Back Connection Portion
21 Adhesive Layer
23 Protective Film
24 First Conductive Line
25 Second Conductive Line
26 First Recess
27 Second Recess
28 Third Recess
31 Adhesion Layer
32 Conductive Layer
33 Seed Layer
34 Body Layer
38 Blackened Layer
Cp Conductive Particle
R1 First Region
R2 Second Region
R3 Connection Region

1. A conductive film provided with a first region and a second region, comprising:
a substrate;
at least one first conductive line provided on the substrate; and
at least one second conductive line provided on the substrate,
the substrate having
at least one first groove located in the first region, extending linearly, and having a bottomed shape, and
at least one second groove located in the second region, extending linearly, and having a bottomed shape,
the first conductive line and the second conductive line including a conductive layer made of a conductive material and embedded in each of the first groove and the second groove,
the first conductive line having at least one first recess recessed from an opening side of the first groove in a thickness direction of the substrate in a cross section,
the second conductive line having at least one second recess recessed from an opening side of the second groove in the thickness direction of the substrate in a cross section,
the first groove and the second groove being configured such that a groove width dimension of the second groove is greater than a groove width dimension of the first groove,
the first recess and the second recess being configured such that a recess width dimension of the second recess is greater than a recess width dimension of the first recess and a recess depth dimension of the second recess is greater than a recess depth dimension of the first recess.

2. The conductive film of claim 1, wherein
the groove width dimension of the first groove is 0.5 μm or more and 3.0 μm or less,
the groove width dimension of the second groove is 8.0 μm or more and 12.0 μm or less, and
a groove depth dimension of each of the first groove and the second groove is 0.5 μm or more and 2.0 μm or less.

3. The conductive film of claim 1, wherein
the first recess and the second recess are configured such that the recess depth dimensions thereof are 0.004 μm or more and 7.0 μm or less.

4. The conductive film of claim 3, wherein
the second groove and the second recess are configured such that a value obtained by dividing the recess depth dimension by the groove width dimension is 0.01 or more and 0.4 or less.

5. The conductive film of claim 1, wherein
the second region includes a connection region where an anisotropic conductive resin material containing a plurality of conductive particles is able to be disposed on a surface of the substrate,
the second groove is configured such that part thereof is located in the connection region, and
the second conductive line is configured such that the second recess located in the connection region has such a size that the second recess is contactable with each of the plurality of conductive particles.

6. The conductive film of claim 5, wherein
the second recess located in the connection region is configured such that a cross-sectional shape of an outer surface of the second recess is curved.

7. The conductive film of claim 5, wherein
the second recess located in the connection region is configured such that a cross-sectional shape of an outer surface of the second recess is an arc shape, and
the second recess located in the connection region is configured such that a radius of curvature of the arc shape is greater than a radius of curvature, which is a particle size, of each of the plurality of conductive particles.

8. The conductive film of claim 1, wherein
the first conductive line further includes a blackened layer stacked on an opening side of the first recess on the conductive layer.

9. The conductive film of claim 1, wherein
the first conductive line further includes at least one third recess, and
a recess width dimension of the third recess is less than the recess width dimension of the first recess, and a recess depth dimension of the third recess is less than the recess depth dimension of the first recess.

10. The conductive film of claim 1, wherein
the second conductive line further includes at least one third recess, and
a recess width dimension of the third recess is less than the recess width dimension of the second recess, and a recess depth dimension of the third recess is less than the recess depth dimension of the second recess.
